(19) United States
(12) Patent Application Publication
(10) Pub. No.: US 2025/0390620 A1
(43) Pub. Date: Dec. 25, 2025

(54) COMPUTERIZED TECHNIQUES FOR OPTIMIZED FLOORPLAN GENERATION

(71) Applicant: Dream Technologies Inc., Denver, CO (US)

(72) Inventors: David MACE, San Francisco, CA (US); Tiger SUN, San Francisco, CA (US); David ZHU, San Francisco, CA (US)

(21) Appl. No.: 19/282,989

(22) Filed: Jul. 28, 2025

Related U.S. Application Data
(63) Continuation of application No. 18/927,467, filed on Oct. 25, 2024, now abandoned.
(60) Provisional application No. 63/662,158, filed on Jun. 20, 2024.

(51) Int. Cl. G06F 30/12; G06F 30/13

(52) U.S. Cl. CPC G06F 30/12; G06F 30/13

(57) ABSTRACT

Systems, methods, apparatuses, and computer program products of a user interface configured for automated generation and optimization of floorplan designs. One method may include automatically generating a plurality of floorplans. At least one of the room's corner offsets is determined after at least one other room's position has been determined. The method further includes scoring a plurality of generated floorplans according to a scoring function; calculating, for at least one generated floorplan, whether it has a path with width at least as large as a number from a door of the respective generated floorplan to an exit; displaying, in an interactive computerized user interface, a subset of the generated plurality of floorplans that has been selected based on the scores of the floorplans; and based upon input from the interactive computerized user interface, transmitting at least one of the generated plurality of floorplans.

### CROSS REFERENCE TO RELATED APPLICATION

This application is a continuation of the co-pending U.S. patent application titled, “COMPUTERIZED TECHNIQUES FOR OPTIMIZED FLOORPLAN GENERATION,” filed on Oct. 25, 2024, having Ser. No. 18/927,467, which claims the priority benefit of U.S. provisional application titled, “COMPUTERIZED TECHNIQUES FOR OPTIMIZED FLOORPLAN GENERATION”, having Ser. No. 63/662,158, filed on Jun. 20, 2024. The subject matter of these related applications is hereby incorporated herein by reference.

### TECHNICAL FIELD

Some example embodiments may generally relate to computer-aided architectural designs, and more specifically, to systems and/or methods of a user interface configured for automated generation and optimization of floorplan designs.

### BACKGROUND

Traditionally, architects design floorplans through a creative and iterative process that integrates multiple considerations, such as spatial requirements, functional requirements, aesthetic preferences, and building regulations. Architects begin by identifying the type of building needed by the client (e.g., residential, commercial, industrial, educations, etc.), the size and types of rooms needed, budget constraints, and any room-specific requirements (e.g., accessibility features).

### SUMMARY

In accordance with some example embodiments, a method may include automatically generating a plurality of floorplans. For each floorplan of a plurality of floorplans, the method may further include determining a position to place a room within a respective floorplan based upon a position of a structural support, and creating a room within the respective floorplan, wherein at least one of the room's corner offsets is determined after at least one other room's position has been determined. The method may further include scoring a plurality of generated floorplans according to a scoring function; calculating, for at least one generated floorplan, whether it has a path with width at least as large as a number from a door of the respective generated floorplan to an exit; displaying, in an interactive computerized user interface, a subset of the generated plurality of floorplans that has been selected based on the scores of the floorplans; and based upon input from the interactive computerized user interface, transmitting at least one of the generated plurality of floorplans.

The apparatus may further include means for scoring a plurality of generated floorplans according to a scoring function; means for calculating, for at least one generated floorplan, whether it has a path with width at least as large as a number from a door of the respective generated floorplan to an exit; means for displaying, in an interactive computerized user interface, a subset of the generated plurality of floorplans that has been selected based on the scores of the floorplans; and based upon input from the interactive computerized user interface, means for transmitting at least one of the generated plurality of floorplans.

In accordance with various example embodiments, a non-transitory computer readable medium may include program instructions that, when executed by an apparatus, cause the apparatus to perform at least a method. The method may include automatically generating a plurality of floorplans. For each floorplan of a plurality of floorplans, the method may further include determining a position to place a room within a respective floorplan based upon a position of a structural support, and creating a room within the respective floorplan, wherein at least one of the room's corner offsets is determined after at least one other room's position has been determined. The method may further include scoring a plurality of generated floorplans according to a scoring function; calculating, for at least one generated floorplan, whether it has a path with width at least as large as a number from a door of the respective generated floorplan to an exit; displaying, in an interactive computerized user interface, a subset of the generated plurality of floorplans that has been selected based on the scores of the floorplans; and based upon input from the interactive computerized user interface, transmitting at least one of the generated plurality of floorplans.

In accordance with some example embodiments, a computer program product may perform a method. The method may include automatically generating a plurality of floorplans. For each floorplan of a plurality of floorplans, the method may further include determining a position to place a room within a respective floorplan based upon a position of a structural support, and creating a room within the respective floorplan, wherein at least one of the room's corner offsets is determined after at least one other room's position has been determined. The method may further include scoring a plurality of generated floorplans according to a scoring function; calculating, for at least one generated floorplan, whether it has a path with width at least as large as a number from a door of the respective generated floorplan to an exit; displaying, in an interactive computerized user interface, a subset of the generated plurality of floorplans that has been selected based on the scores of the floorplans; and based upon input from the interactive computerized user interface, transmitting at least one of the generated plurality of floorplans.

In accordance with certain example embodiments, an apparatus may include at least one processor and at least one memory storing instructions that, when executed by the at least one processor, cause the apparatus at least to automatically generate a plurality of floorplans. The at least one memory and instructions, when executed by the at least one processor, may further cause the apparatus at least to, for each floorplan of a plurality of floorplans, determine a position to place a room within a respective floorplan based upon a position of a structural support, and creating a room within the respective floorplan, wherein at least one of the room's corner offsets is determined after at least one other room's position has been determined. The at least one memory and instructions, when executed by the at least one processor, may further cause the apparatus at least to score a plurality of generated floorplans according to a scoring function; calculate, for at least one generated floorplan, whether it has a path with width at least as large as a number from a door of the respective generated floorplan to an exit; display, in an interactive computerized user interface, a subset of the generated plurality of floorplans that has been selected based on the scores of the floorplans; and based upon input from the interactive computerized user interface, transmit at least one of the generated plurality of floorplans.

In accordance with various example embodiments, an apparatus may include generating circuitry configured to automatically generate a plurality of floorplans. The apparatus may further include determining circuitry configured to for each floorplan of a plurality of floorplans, determine a position to place a room within a respective floorplan based upon a position of a structural support, and creating a room within the respective floorplan, wherein at least one of the room's corner offsets is determined after at least one other room's position has been determined. The apparatus may further include scoring circuitry configured to score a plurality of generated floorplans according to a scoring function; calculating circuitry configured to calculate, for at least one generated floorplan, whether it has a path with width at least as large as a number from a door of the respective generated floorplan to an exit; displaying circuitry configured to display, in an interactive computerized user interface, a subset of the generated plurality of floorplans that has been selected based on the scores of the floorplans; and based upon input from the interactive computerized user interface, transmitting circuitry configured to transmit at least one of the generated plurality of floorplans.

### BRIEF DESCRIPTION OF THE DRAWINGS

For a proper understanding of example embodiments, reference should be made to the accompanying drawings, wherein:

FIGS. 1A and 1B illustrate an example of a user interface for interacting with an automatic floorplan generator according to various example embodiments;

FIGS. 2A-2C illustrate an example of an input file according to some example embodiments;

FIG. 3 illustrates an example of a 2D probability distribution that a seed position of a room may be sampled from according to certain example embodiments;

FIG. 4 illustrates a method for automatically generating a floorplan according to some example embodiments;

FIG. 5 illustrates a method for placing a room according to various example embodiments;

FIG. 6 illustrates a method for placing a door according to certain example embodiments;

FIG. 7 illustrates a method for calculating a chosen width and depth for a room that was defined to be an approximate area according to some example embodiments;

FIG. 8 illustrates a method for calculating the position of a room after the seed point, width, and depth are known according to various example embodiments;

FIG. 9 illustrates a method for optimizing a floorplan according to certain example embodiments;

FIG. 10 illustrates a method for determining a number of isolated components according to some example embodiments;

FIG. 11 illustrates a method for calculating dead space within the floorplan according to various example embodiments;

FIG. 12 illustrates a method for calculating short segments in a floorplan according to certain example embodiments;

FIG. 13 illustrates a method for measuring the simplicity of a layout according to some example embodiments;

FIG. 14 illustrates an alternative method for measuring of the simplicity of a layout according to various example embodiments;

FIG. 15 illustrates a method for measuring the simplicity of shapes of open areas according to certain example embodiments;

FIG. 16 illustrates a method for measuring the openness of an open space according to some example embodiments;

FIG. 17 illustrates a method for measuring the simplicity of the hallway path according to various example embodiments;

FIG. 18 illustrates a method for automatically generating a plurality of floorplans; and

FIG. 19 illustrates an example of a network device according to some example embodiments.

### DETAILED DESCRIPTION

It will be readily understood that the components of certain example embodiments, as generally described and illustrated in the figures herein, may be arranged and designed in a wide variety of different configurations. Thus, the following detailed description of some example embodiments of systems, methods, apparatuses, and computer program products of a user interface configured for automated generation and optimization of floorplan designs is not intended to limit the scope of certain example embodiments, but is instead representative of selected example embodiments.

Architects may develop initial floorplan designs in a logical manner with a variety of software tools, such as drafting tools and computer-aided design (CAD) software (e.g., AutoCAD, SketchUp, DraftSight). Architects may also consider ease of movement through the floorplan through hallways and stairs.

After creating an initial floorplan layout satisfying the minimal requirements, architects may review the design with the client, and revise according to any feedback or concerns they may have. Other specialists may be consulted as well, such as interior designers and Heating, Ventilation, and Air Conditioning (HVAC) engineers, on how the design may be improved based on their specializations. This iterative exchange and redesign process can be extremely inefficient.

Drafting techniques are currently limited to generating simplistic floorplans, lacking a variety of complex building conditions (e.g., posts, flexible room sizes, complex layouts, etc). Certain example embodiments described herein may have various benefits and/or advantages to overcome the disadvantages described above. For example, certain example embodiments may improve the automatic generation of optimized floorplans by enabling computers to create floorplans that handle a variety of complex building conditions rather than just very simple building requirements.

Various example embodiments may generate optimized floorplans that may be displayed on a computer and/or printed and viewed by an owner or user of the physical space represented by the floorplan, allowing a user to approve or reject the floorplan. Additional floorplans may be generated and displayed or viewed in printed form if the owner or user of the space desires to see additional generated floorplans. Thus, certain example embodiments discussed below are directed to improvements in computer-related technology.

According to certain example embodiments, an optimal floorplan can satisfy or balance multiple conflicting requirements, such as placing certain rooms a minimum or maximum distance from each other, clustering types of rooms (e.g., meeting rooms), aligning the exterior walls of rooms, placing doorways within an overall context of the floorplan, satisfying building code requirements (e.g., hall widths), minimizing underutilized space, reserving floor space for open office areas, creating equity between different rooms or areas, utilizing natural light, optimizing HVAC and heating/cooling functionality, complying with building codes (e.g., fire escape paths), satisfying aspect ratios (i.e., width/length), designing rooms that are properly oriented to accommodate fixtures/furniture/elements, minimizing construction costs, optimizing for layouts that can be cost-effectively constructed robotically, optimizing for layouts that are cost-effectively pre-fabricated, creating optimal aesthetics for the space, optimizing the space relative to uneven ceiling heights, accounting for internal posts and obstructions, accounting for existing rooms, minimizing the number of short segments within the floorplan, optimizing for office spaces to be near the perimeter/center/specific walls of the building, and a variety of other constraints. Thus, some example embodiments may generate floorplans for any building type, including offices, apartments, single family homes, townhouses, restaurants, schools, retail, industrial, hotels, government, high-rises, low-rises, single story, multi-story, and any other type of building.

In general, a floorplan can include rooms, doors, hallways, storage areas, and other non-room space. Floorplans may have fixed and/or moveable elements, such as posts, rooms, cross-beams, and other elements. Rooms can have one or more doors, or even zero doors. Rooms can be connected to hallways, other room, and other non-room spaces. Floorplans may also include open rooms without walls nor exit paths through them (e.g., office area). Rooms may share a wall with an exterior boundary, share a wall with one or more other rooms, or be completely separate.

Exterior boundaries of a floorplan can include walls, doors, windows, posts, and other elements. Exterior boundaries of a floorplan can be straight, diagonal, curved, indented, uneven with elements, built with mullions, and a variety of other configurations. Rooms may also have walls that are diagonal or curved, and may have open walls. Rooms may be defined as fixed dimensions, approximate areas, fixed areas, approximate dimensions, or other formats that define room requirements.

Specific sections of a floorplan may be fully or partially occupied with fixed elements (e.g., staircase, posts, areas below or adjacent to crossbeams), requiring removal of those specific sections from the polygon of possible placement areas.

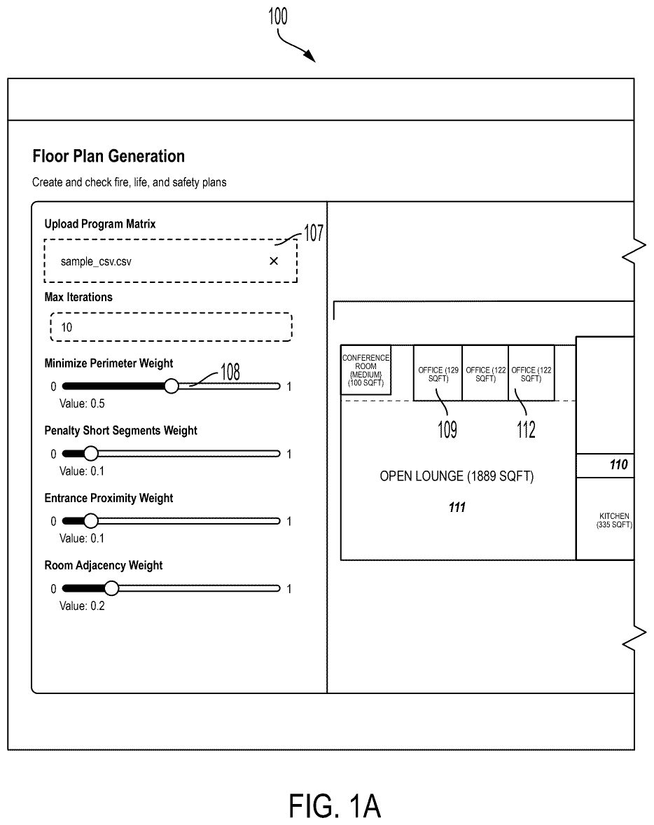

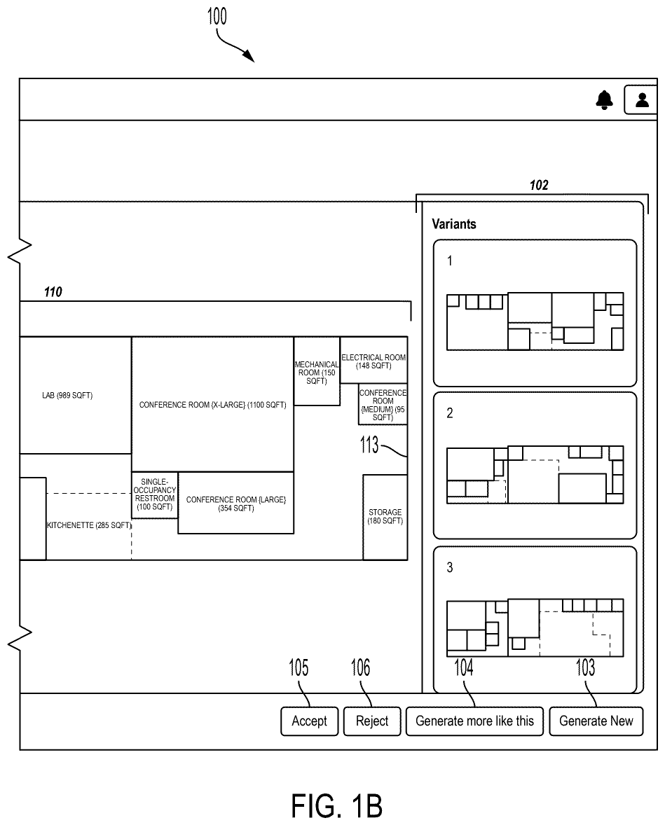

In various example embodiments, a user interface (UI) may be configured to facilitate automatic generation of floorplans, and allow a user to quickly select, approve, and reject generated floorplans. The user may also modify a specific floorplan automatically. FIG. 1 depicts UI 100 configured to enable a user to request automatic generation of a floorplan, and view the resulting generated floorplans. Floorplan 101 may be automatically generated and displayed to the user in UI 100. In certain example embodiments, floorplan 101 may be displayed in the format depicted or any similar format, including a two-dimensional (2D) floorplan or three-dimensional (3D) model, either of which may include other elements. As an example, UI 100 may depict floorplan 101 as part of an architectural plan set view, and may or may not include other elements. Floorplan 101 may be a complete floorplan, or a portion of a larger floorplan. For example, floorplan 101 may represent single or multiple levels (i.e., floors). Floorplan 101 may or may not be editable; for example, if floorplan 101 is editable, the user may be able to resolve any problems with floorplan 101. Floorplan 101 may be used across multiple subsequent UIs, programs, and file formats during the process of automatically generating floorplans. As shown in FIG. 1, floorplan 101 may include any combination of room 109, hallway 110, open space 111, door 112, and exit 113, all generated by the automatic floorplan generator.

UI 100 may also include a set of other automatically generated floorplans 102, which the user may select to display a larger version. The set of other automatically generated floorplans 102 may be displayed in UI 100 and/or may be shown by the user clicking a button.

UI 100 may also include button 103 configured to allow the user to generate a new floorplan to be displayed in UI 100. Similarly, UI 100 may include button 104 configured to allow the user to generate a new floorplan that is similar to floorplan 101 currently being shown to the user. UI 100 may further include button 105 configured to allow the user to accept floorplan 101 being displayed by UI 100. Alternatively, button 106 in UI 100 may be configured to allow the user to reject floorplan 101 being displayed by UI 100, and may initiate generation of a new floorplan to be displayed by UI 100.

UI 100 may also indicate an input file 107 (e.g., comma-separated values (CSV)) containing input parameters for automatically generating a floorplan, similar to the input parameters discussed above (e.g., fixed dimensions, approximate areas, fixed areas, approximate dimensions). Constraints 108 may be configured and set by the user to apply to floorplan 101; constraints 108 may be any format, such as a slide bar, input field, input file (similar to input file 107), radio button, checkbox, dropdown menu providing a variety of options, and/or any other input method.

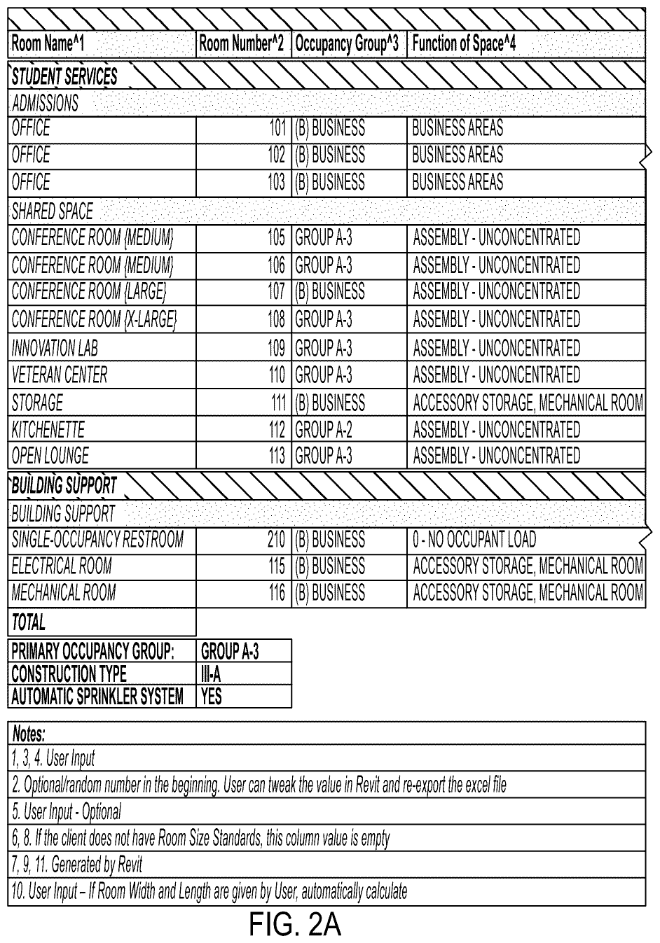

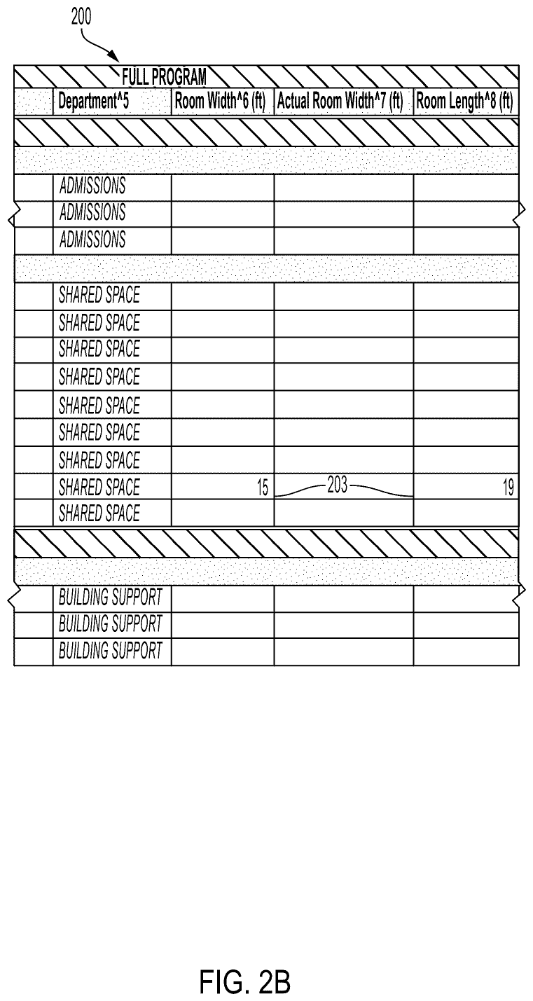

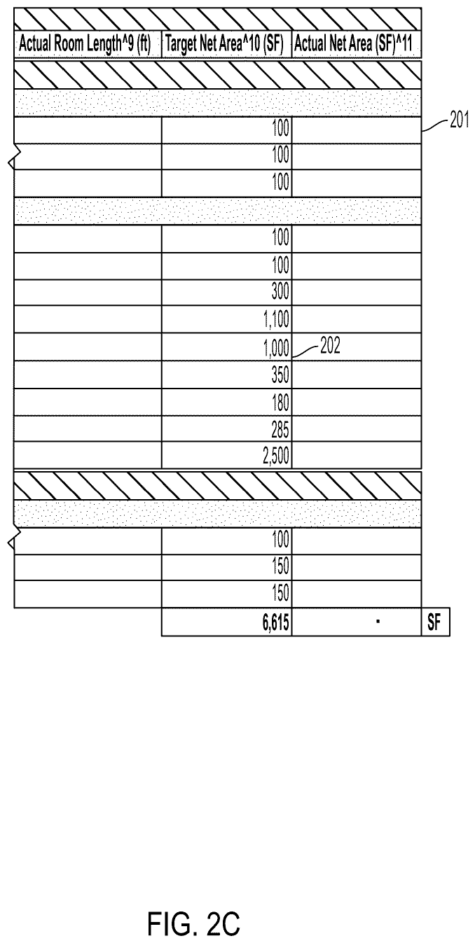

FIG. 2 illustrates input file 200 (similar to input file 107 shown in FIG. 1) that may be input into the automatic floorplan generator. Input file 200 may contain constraints for the automatic floorplan generator to apply when generating rooms within a floorplan. Row 201 specifies a room that the automatic floorplan generator should create; for example, row 201 may be input directly in a UI (similar to UI 100 in FIG. 1) by the user, or input via a file. If a room's target area or dimensions are not specified, a default value for that room type may be used. Area 202 defines a target area for the room specified in row 201, and dimensions 203 define exact dimensions for the room specified in row 201.

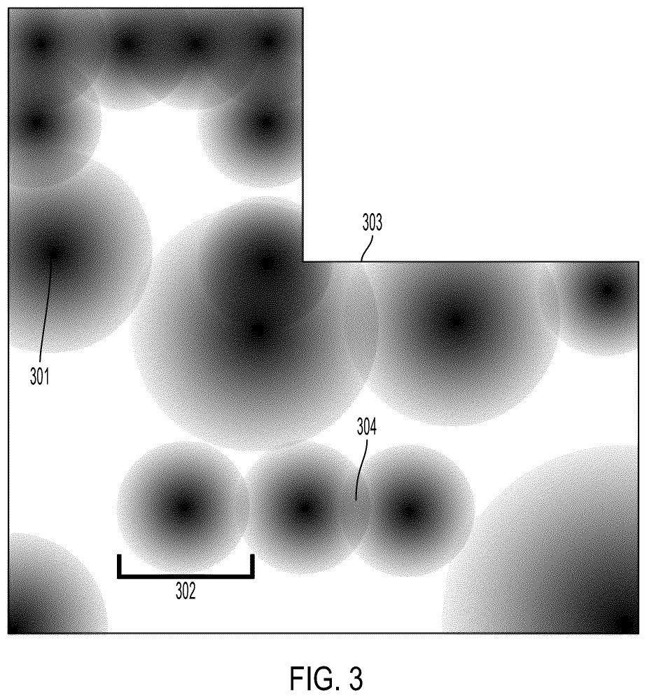

FIG. 3 depicts a 2D probability distribution that a start position of a room is sampled from. 301 denotes the center of the probability distribution for a prospective point, 302 denotes a probability distribution for a prospective point, and 303 denotes an outer boundary of the floorplan.

Certain example embodiments discussed herein can generate a large number of potential floorplans (e.g., one million initial potential floorplans) using multiple computers and multiple cores per computer. For example, a completely optimized floorplan may be generated and displayed to the user. In some example embodiments, floorplans may be sorted by their level of optimization and displayed to the user, sorted according to an optimization score.

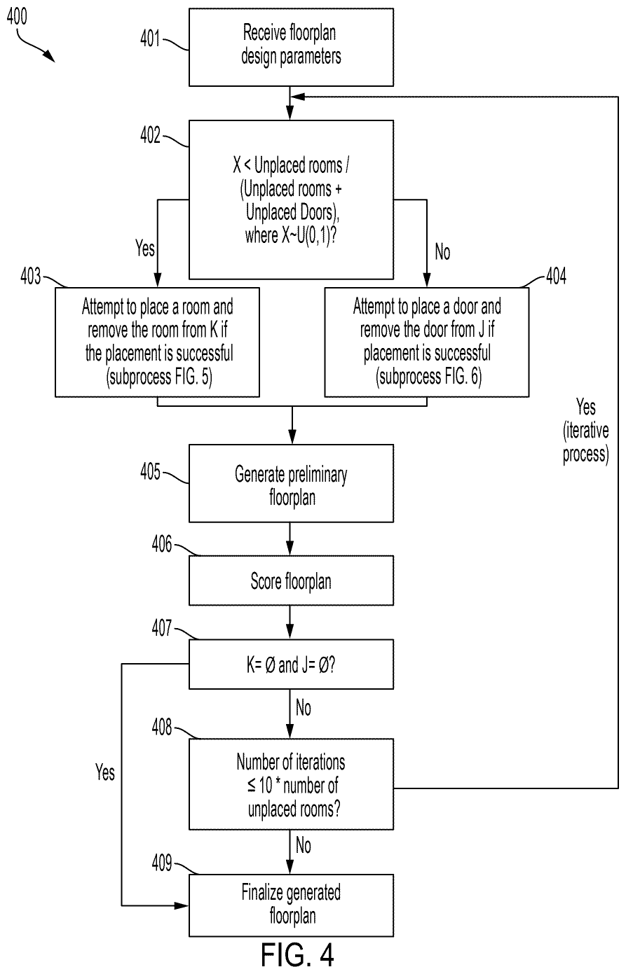

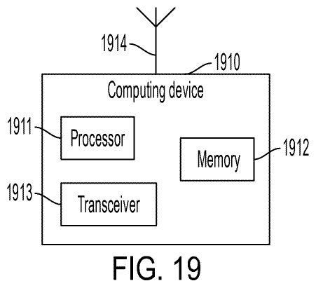

FIG. 4 illustrates an example of a flow diagram of a method 400 for automatically generating a floorplan that may be performed by a computing device, such as computing device 1910 illustrated in FIG. 19, according to various example embodiments.

At step 401, the method may include receiving a variety of floorplan design parameters. For example, K may define a set of unplaced rooms; J may define a set of unplaced doors; R may define a set of placed room polygons; D may define a set of placed door polygons; B may define the polygon of positions that are inside of the floorplan's outer boundary and not occupied by a room; W may define a set of rooms' walls such that Wᵢ is the set of wall polygons for placed room Rᵢ; L may define the polygon of exterior walls of the floorplan; and F may define a set of generated floorplans.

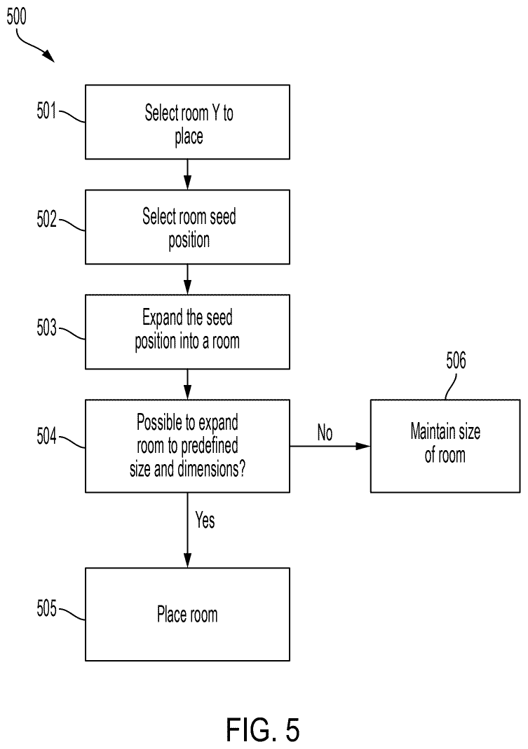

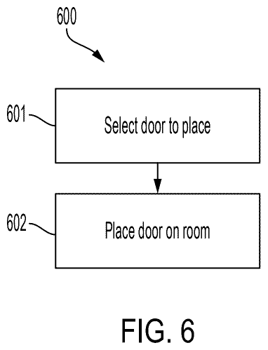

At step 402, the method may further include determining an element to place based upon whether

$$X < \frac{\vert K \vert}{\vert K \vert + \vert J \vert}$$

where X˜ [symbol] (0,1), K is unplaced rooms, and J is unplaced doors. For example, upon determining that

$$X < \frac{\vert K \vert}{\vert K \vert + \vert J \vert}$$

where X˜ [symbol] (0,1), at step 403, the method may include attempting to place a room and removing the room from K if the placement is successful; the process of placing a room at step 403 is described in more detail below with respect to FIG. 5. Otherwise, at step 404, the method may include attempting to place a door and removing the door from J if the placement is successful; the process of placing a door at step 404 is described in more detail below with respect to FIG. 6. Furthermore, a door leading to a room may be generated immediately after the room is generated. A set of doors to be generated may include doors from the space to the exterior of the building and/or through dividing walls.

At step 405, the method may include generating a preliminary floorplan.

At step 406, the method may further include scoring a generated floorplan according to a scoring function. The method may include scoring a plurality of generated floorplans according to a scoring function.

At step 407, the method may include determining whether K=Ø and J=Ø (i.e., whether there are no more rooms and no more doors to place).

If K≠Ø or J≠Ø, then at step 408, the method may include determining whether the number of iterations already performed≤10*the starting number of rooms to place. If the number of iterations already performed≤10*the starting number of rooms to place, the method may return to step 402.

However, if step 407 yields K=Ø and J=Ø, or the number of iterations already performed>10*|K| at step 408, then the process proceeds to step 409, wherein the method may include finalizing a generated floorplan.

FIG. 5 illustrates an example of a flow diagram of a method 500 for placing a room that may be performed by a computing device, such as computing device 1910 illustrated in FIG. 19, according to various example embodiments.

At step 501, the method may include selecting a room Y for placement according to P(Y=x)=A(x)/Σ_{x∈K}A(x), ∀x∈K, where A(x) is the goal area of the room.

At step 502, the method may further include determining a position to place a room within a respective floorplan relative to one or more seed positions (e.g., a position of a structural support), for example, by selecting a room seed position by

$$Z ∼ {1}_{B} * {\sum }_{i = 1}^{n} N ( {μ}_{i} , {\sum }_{i} ) ,$$

$$where$$

$${1}_{B} ( x ) = \{ \begin{matrix}1 & if x ∈ B \\ 0 & otherwise\end{matrix} ,$$

μ is the set of position for each “prospective point,” Σ is the set of precalculated variance for each “prospective point,” and n is the number of prospective points. The method may determine a position to place a room within a respective floorplan based upon a position of a structural support. Each μᵢ and Σᵢ may be multi-dimensional (e.g., 2D). This calculation may sample points from within the floorplan space that are not already assigned to rooms, with the probability of picking a position depending on convoluted spatial probabilities influenced by the prospective points.

At step 503, the method may further include expanding the room seed position into the room selected at step 501, for example, by creating a room within the respective floorplan, wherein at least one of the room's corner offsets is determined after at least one other room's position has been determined.

For example, in certain example embodiments, a random element may be selected from a set where each element has a different probability of being selected (e.g., using NumPy random choice). For example, a value of 1_{B} may be determined for an arbitrary point by an algorithm (e.g., the Ray casting algorithm) that determines whether a point is within the bounds of a polygon. The value of [symbol] (μᵢ,Σᵢ) may be calculated including by calculating a normal distribution in two dimensions. Z may be approximated by choosing a large random set of points (e.g., 10,000), determining the value of the function Z for each, and then randomly selecting a point from these, with the probability of selecting each point weighted by the pre-calculated value of Z for each point. In some example embodiments, the number of randomly sampled points may be 100. Σᵢ may be zero for some or all ‘i’.

At step 504, the method may further include determining whether it is possible to expand the room to an adequate size and dimensions.

At step 505, upon determining that the room can be expanded at step 504, the room may be expanded.

At 506, upon determining that the room cannot be expanded at step 504, the room may not be expanded.

FIG. 6 illustrates an example of a flow diagram of a method 600 for placing a door that may be performed by a computing device, such as computing device 1910 illustrated in FIG. 19, according to various example embodiments.

At step 601, the method may include selecting a door M to place by M˜J.

At step 602, the method may further include placing the selected door for room Rᵢ at position N˜(Wᵢ\∪_{W}_{ⱼ}_{∈W,j≠i}Wⱼ)\L. This may place the door in a wall that is not shared with another room or an exterior wall, so the wall may face the internal non-room area. The rotation of the door may be set parallel to the wall, and the orientation may be set such that the door opens to the outside of the room. The door may be placed so that the door's depth spans the wall's depth (e.g., so that it forms a hole into the room). The door may be placed such that it may be centered at N in the axis that is parallel to the wall; if this would result in the door spanning beyond the room's edge, then the door may be placed at the end of the wall with the minimum gap to the corner required by standard building practices. Calculating the difference of polygons and selecting a random point from within a polygon can both be calculated from existing polygon libraries and methods.

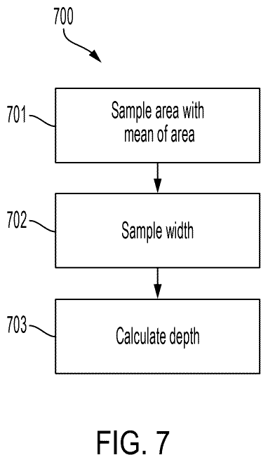

FIG. 7 illustrates an example of a flow diagram of a method 700 for calculating a chosen width and depth for a room that was defined to be an approximate area that may be performed by a computing device, such as computing device 1910 illustrated in FIG. 19, according to various example embodiments.

At step 701, the method may include sampling a chosen area from a normal distribution with mean of the desired area and standard deviation of ST1.

At step 702, the method may further include sampling a chosen width from a normal distribution with mean of square root of the chosen area and standard deviation of ST2.

At step 703, the method may further include calculating the room's depth as the chosen area divided by the chosen width.

In certain example embodiments, ST1 may be various percentages of a desired room's area, such as 10%. In some example embodiments, ST2 may be various percentages of the square root of the desired room's area, such as 10%. In various example embodiments, a maximum aspect ratio may be preset, and the room width may be recalculated if it would make the aspect ratio larger than the maximum aspect ratio.

In certain example embodiments, for a room that was defined to be specific dimensions, a swapping value may be randomly sampled from the set (false, true). If the swapping value is false, then the room width may be in the x direction, and the room depth may be in the y direction. If the swapping value is true, then the room depth may be in the x direction, and the room width may be in the y direction.

In another embodiment, if the room is specified to have variable dimensions, then a random sample from a distribution (e.g., uniform distribution) may be taken of the target ratio of width to depth for a range of minimum to maximum ratio (e.g., 1:3 to 3:1). The starting width and depth from the ratio and the target area of the room may also be determined.

In certain example embodiments, the floorplan generator may store a list of minimum dimensions for each room type. The floorplan generator may then select a new seed if the room will have a dimension less than the minimum. If the room is specified to have fixed dimensions, then the width and depth may be the fixed dimensions.

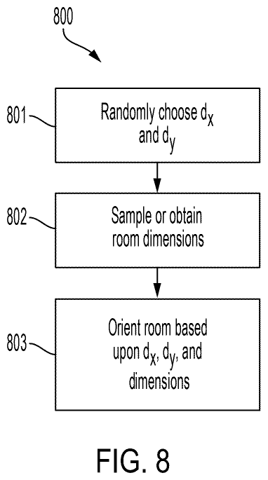

FIG. 8 illustrates an example of a flow diagram of a method 800 for calculating the position of a room after the seed point, width, and depth are known that may be performed by a computing device, such as computing device 1910 illustrated in FIG. 19, according to various example embodiments.

At step 801, the method may include randomly choosing dₓ from the set (positive, negative) and d_{y} from the set (positive, negative).

At step 802, the width and depth of the room may be sampled or pulled from an input.

At step 803, the method may further include orienting the room based upon dₓ, d_{y}, and the dimensions. The room may have the dimensions determined previously. For example, if dₓ is the key “positive”, then the room may be oriented as far in the positive x direction as possible, while still including the seed point in the room, but not overlapping with any other room polygon or exceeding the floorplan boundary. Alternatively, if dₓ is the key “negative”, then the room may be oriented as far in the negative x direction as possible, while still including the seed point in the room, but not overlapping with any other room polygon or exceeding the floorplan boundary. If d_{y} is the key “positive”, then the room may be oriented as far in the positive y direction as possible, while still including the seed point in the room, but not overlapping with any other room polygon or exceeding the floorplan boundary. Alternatively, if d_{y} is the key “negative”, then the room may be oriented as far in the negative y direction as possible, while still including the seed point in the room, but not overlapping with any other room polygon or exceeding the floorplan boundary. This method may improve overall clustering and alignment of the floorplans' rooms.

In some example embodiments, prospective points may include at least one position relative to a post or other structural support (e.g., the center of a structural support); may include at least one position of a corner of the portion of the floorplate that is not already occupied by a room; may include at least one position relative to isolated windows (e.g., the center of a window); may include at least one position of a center of a skylight; may include at least one location of an existing utility connection; may include at least one position of a mullion on a curtain wall; may include at least one random location from within the portion of the floorplate that is not already occupied by a room. Other major distinct points within the floorplan may be additionally be included in prospective points.

In various example embodiments, Σᵢ for each ‘prospective point’ may vary. For example, the standard deviation may be 5 feet in all directions for centers of isolated windows; 2 feet in all directions for curtain wall mullions; 10 feet in all directions for existing utility connections; 10 feet in all directions for skylight centers; 1 foot in all directions for internal posts; 2 feet in all directions for corners; and 15 feet in all directions for randomly selected positions. However, any distances may be used.

In certain example embodiments, after each room is placed, the room may be stretched so as to align an edge of the room with an edge of a different room in the floorplan. For example, when placing room R, if there is another room's corner within X feet of any of room R's corners, a wall of room R may be moved so that room R's corner is at the same position as the other room's corner; X may be a percentage (e.g., 15%) of a measurement (e.g., depth in the direction perpendicular to the wall or the longest diagonal distance) of room R. As another example, X may be a fixed number of feet. This stretching process may be not performed for rooms that are specified or chosen to have fixed dimensions. This may cause two rooms to share a wall. This may cause two rooms to have walls that are parallel and touching at a corner. This may be performed multiple times for various walls of room.

In some example embodiments, a square area with the width of the door may be placed in front of the door (e.g., outside the room) and included as part of the room. This may ensure that other spaces are not placed in front of the door during generation.

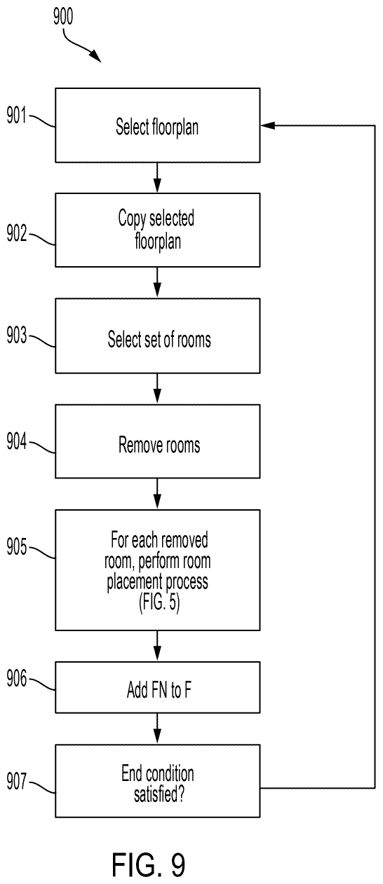

FIG. 9 illustrates an example of a flow diagram of a method 900 for optimizing a floorplan that may be performed by a computing device, such as computing device 1910 illustrated in FIG. 19, according to various example embodiments.

At step 901, the method may include selecting a floorplan FC∈F by P(FC=x)=PE(x)/Σ_{x∈F}PE(x), ∀x∈F where PE(x) may be a pre-calculated level of perfection of the floorplan. In some embodiments, FC may be the floorplan with the highest score, rather than a weighted random selection.

At step 902, the method may further include generating a copy of FC, FN.

At step 903, the method may further include selecting a set of rooms RS⊆R*, where R* is the set of rooms in FN.

At step 904, the method may further include removing the rooms RS from FN.

At step 905, the method may further include, for each removed room, sequentially performing the room placement process described in FIG. 5.

At step 906, the method may further include adding FN to F, which may be the set of all floorplans generated.

At step 907, the method may further include repeating this process until an end condition is satisfied. For example, the size of the set RS may begin at 4 and sequentially decline whenever the best value of PE(x), ∀x∈F has not increased in the previous 10,000 iterations. When the size of RS becomes 0, the process may end. In other example embodiments, the size of the set RS may vary from 1 to the total number of rooms in the floorplan. In other embodiments, the size of RS can be chosen at random; be constant over time; increase over time; decrease in a different schedule over time; be determined as a function of the current best value of PE(x), ∀x∈F; increase or decrease non-linearly; be altered based on a function of a subset or complete set of the floorplans; be altered based on a function of the iteration process's progress curve; and/or be altered by a combination of multiple of these options.

In some example embodiments, the optimization function may be performed a predetermined number of time (e.g., 1 million) after the set of initial floorplans has been generated and scored. If the user instructs the floorplan generator to generate similar floorplans (e.g., clicks a “generate more like this” button), the optimization function may be performed 1 million times, and the input set of floorplans to start is just the currently viewed floorplan.

For example, the floorplans in F may be sorted by their scores, and the best generated one or more floorplans may be displayed to the user.

In various example embodiments, the door to a room may be removed at the same time that the room is removed. Similarly, a door may be removed and replaced separately from a room.

In certain example embodiments, multiple functions may be combined to calculate the value of PE (FC) for a given floorplan FC. For example, PE may be calculated as PE(x)=∧_{b}_{ᵢ}_{∈b} bᵢ(x)*Σ_{c}_{ᵢ}_{∈c} Cᵢ(x), where b may be a set of binary functions that output 0 or 1, c may be a set of continuous functions that output between 0 and 1, and a larger value of PE(x) may be preferable. As an example, the functions may be combined in a weighted sum. As another example, some or all of the weights may be manually set (e.g., either by the user or as a preset). As another example, all of the binary and continuous functions may be multiplied together (or their logs are summed together). As another example, only a subset of these functions is used to calculate PE. As another example, all of the functions are summed together, including the binary functions.

Various example embodiments may include performing functions on polygons, where Rᵢ is a room polygon, Wᵢ is a wall polygon, Sᵢ is a non-room space, and T is a polygon defined by the external bounds of the building. For example, a binary function may determine whether all rooms are within the external bounds of the floorplan by checking whether area(T∪∪_{R}_{ᵢ}_{∈R} Rᵢ)==area(T) is true. The union of arbitrary polygons may be calculated by a polygon library, the area of each polygon is calculated by a polygon library, and the area of T can be referenced from a previously stored value.

As an example, a binary function may determine whether rooms overlap by checking whether area (∪_{R}_{ᵢ}_{∈R} Rᵢ)==Σ_{R}_{ᵢ}_{∈R} area (Rᵢ) is true. The union of arbitrary polygons may be calculated by a polygon library, and the area of each polygon may be calculated by a polygon library or recalled from a value stored during creation of each room.

As another example, a binary function may determine whether there is an overlap between a room and a wall by determining whether ∪_{R}_{ᵢ}_{∈R} Rᵢ∩∪_{W}_{ᵢ}_{∈W} Wᵢ≠Ø is true. The union and intersection of arbitrary polygons may be calculated by a polygon library.

In some example embodiments, values of 0 to 1 may be output based, at least, on how well the rooms are clustered. This may be calculated according to

$$\frac{CO \times Area ( CH ( PO ) )}{Perimeter ( PO )} ,$$

wherein PO may be a multi-polygon that is the union of polygons of rooms in the floorplan, CH(PO) may be the convex hull of corner points of the multi-polygon PO, and CO may be a correction coefficient. CO may be any number from 0 to any number greater than 1 (e.g., 0.1). The perimeter of the multi-polygon PO may be calculated by summing the lengths of its edges.

As discussed throughout this disclosure, the Minkowski sum of a polygon P and a circle C centered at the origin may be the set of all points obtained by translating each point of the polygon by each point on the circle, effectively buffering the polygon by the radius of the circle. The Minkowski difference of a polygon P and a circle C centered at the origin is the set of all points obtained by translating each point of the polygon by the negative of each point on the circle, effectively shrinking the polygon by the radius of the circle. The shrinking function may be used to determine whether there are areas with a dimension smaller than an amount.

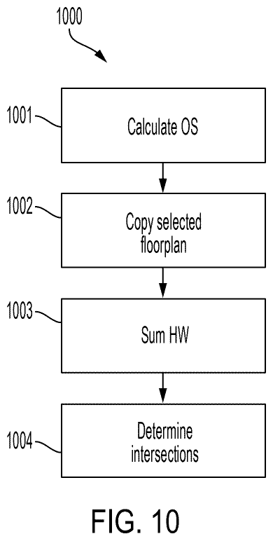

Furthermore, various example embodiments may calculate whether a floorplan has a path with width at least as large as a number from a door of the respective generated floorplan to an exit. This number may be the width required by the building code applying to this building. As an example, FIG. 10 depicts a method 1000 for determining a binary metric for this. At step 1001, the non-room space OS=T\∪_{R}_{ᵢ}_{∈R} Rᵢ may be calculated, and at step 1002, a Minkowski difference of OS and C may be calculated, where C is a circle of width d centered at the origin. The method may include calculating, for at least one generated floorplan, whether it has a path with width at least as large as a number from a door of the respective generated floorplan to an exit. The Minkowski difference may be determined by a polygon library. The number of discrete polygons may also be determined by a polygon library. The value of d may be 1 inch less than half of the required hallway width from the building code.

At step 1003, the Minkowski sum HW of the result of step 1002 and C may be calculated, where C is a circle of width d centered at the origin. At step 1004, if all doors intersect or are directly next to HW, and HW is a single polygon, the method may return 1; otherwise, the method may return 0.

A floorplan with multiple sections that are entirely separated by walls or obstacles may first be separated into each of these sections, then this score may be calculated on each of the sections, then the total score may be the multiplication of the score for each section.

Certain example embodiments may determine how optimally a floorplan satisfies rooms that are desirable to be close together and desirable to be far apart. This may be calculated according to Σ_{R}_{ᵢ}_{∈R} Σ_{R}_{ⱼ}_{∈R} WE (Rᵢ, Rⱼ)*D(Rᵢ, Rⱼ), where D may be a function that returns the distance between two rooms, and WE may return a weight that differs for each pair of room types.

WE may return a positive value for each pair of rooms Rᵢ and Rⱼ that are supposed to be close, a negative value for each pair of rooms Rᵢ and Rⱼ that are supposed to be far apart, and 0 in all other positions. For example, the positive values may be 1, and the negative values may be −1.

In some example embodiments, the function D (Rᵢ,Rⱼ) may return a Cartesian distance between the center of Rᵢ and the center of Rⱼ. In various example embodiments, the function D may be measured between rooms' corner points, center points, near points, or far points. In some example embodiments, the distance may be calculated by a Cartesian distance or path distance between the points. In some example embodiments, the function D may be trimmed or passed into another function that outputs to a different space. In other example embodiments, the function D may be trimmed from a minimum distance to a maximum distance. Alternatively, the function D may have a superlinear, sublinear, exponential, logarithmic, or polynomial function applied to the Cartesian distance value. In certain example embodiments, the mapping may result in a larger function difference between small Cartesian distances, to prioritize floorplans where desired rooms are very close or directly touching. In some example embodiments, rooms that directly touch may result in a better value than rooms that are close but not touching. In certain example embodiments, the sum of the weighted distances may be converted to a value between −1 and 1 by dividing by Σ_{R}_{ᵢ}_{∈R} Σ_{R}_{ⱼ}_{∈R} D(Rᵢ, Rⱼ).

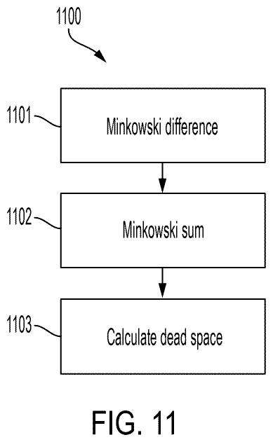

Certain example embodiments may calculate dead space, which is the non-room space that has a dimension less than a threshold. For example, as shown in method 1100 of FIG. 11, at step 1101, a Minkowski difference A1 of ∪_{S}_{ᵢ}_{∈S} Sᵢ and C may be calculated, where C is a circle of width d centered at the origin. At step 1102, a Minkowski sum A2 of the result of the previous step and C may be calculated, where C is a circle of width d centered at the origin. At step 1103, the method may include calculating dead space as A3=(∪_{S}_{ᵢ}_{∈S} Sᵢ)\A2. For example, the value of d may be 1″ less than half of the required hallway width from the building code. To convert the dead space value from 0 to 1, the area of dead space (A3) may be divided by the total floorplan area. In various example embodiments, a binary function may return 0 if there is any dead space and 1 otherwise.

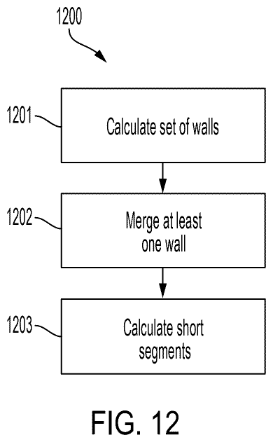

Some example embodiments may calculate short segments in a floorplan according to the method shown in FIG. 12. For example, at step 1201, the method may include calculating the set of walls (WS) that are only present in exactly one of {W₁, W₂, . . . }. At step 1202, the method may include forming WM by merging the walls within WS that are colinear and parallel. At step 1203, the method may further include calculating the number of short segments, |{x∈WM|L(x)<t}|, where L(x) is the length of wall x and ‘t’ is a constant. For example, the value of ‘t’ may range from 1 foot to 100 feet (e.g., 5 feet); the function's value may be 0 if any short segment is present and 1 otherwise. Various example embodiments may include multiple functions to calculate short segments at different thresholds. For example, one function may calculate very small, short segments that suggests a misalignment of rooms, and results in a binary output that is 0 if any short segments are present. Another function may calculate a number of short segments, using a higher threshold and each short segment only adds a fraction of 1 to the function's value; for example, the fraction may be 0.1, and the total value may be capped at 1.

Various example embodiments may calculate whether multiple doors to a room are too close together according to Σ_{DR}_{ᵢ}_{∈DR}|{(p, q)∈DRᵢ×DRᵢ|dist(p, q)≤dᵢ} |, where dist(p,q) is the Cartesian distance between p and q, DRᵢ is the set of centers of doors in room Rᵢ, DR is the set of DRᵢ for all Rᵢ, and dᵢ is a threshold. For example, dᵢ may be ⅓ of the longest diagonal in Rᵢ and Rⱼ. As another example, dᵢ may be a constant across all rooms. As another example, dᵢ may be an arbitrary function of the shape and/or size of room Rⱼ. In some example embodiments, the function may be 0 if the count is greater than 0; otherwise, the function may be 1. In various example embodiments, there may be a linear, sublinear, polynomial, logarithmic, or other function that maps the count to the function output.

Certain example embodiments may include a binary function configured to determine whether each room has the correct number of doors. In addition, one function may include a binary function configured to determine whether each room in the floorplan has a door and each room has the specified number of doors from the input.

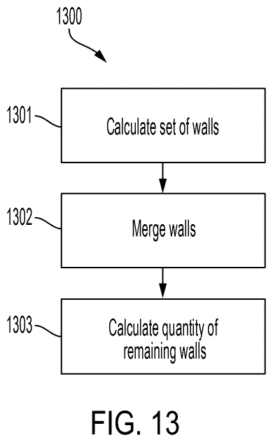

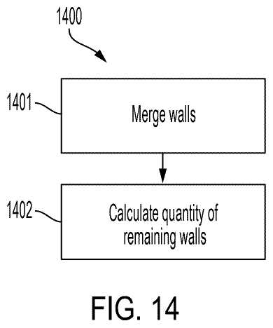

Various example embodiments may measure the simplicity of the layout, more specifically, the number of distinct walls in the layout. As shown in the method of FIG. 13, step 1301 may include calculating the set of walls WS that are only present in exactly one of {H₁, H₂, . . . }. This may remove walls between rooms. At step 1302, the method may further include merging the walls within WS that are colinear and parallel, to form WM. At step 1303, the method may further include calculating |WM|. An alternative procedure for measuring the simplicity of the layout is depicted in FIG. 14, where at step 1401, WM may be calculated by flattening H, then merging any walls that are colinear and parallel. At step 1402, |WM| may be calculated. The procedure shown in FIG. 13 may ignore walls that are directly between rooms, while the procedure shown in FIG. 14 may include walls that are directly between rooms. In both FIGS. 13 and 14, the output value may be divided by 100 but be capped at 1.

In certain example embodiments, H={H₁, H₂, . . . }. Hᵢ={linearize (PW) for PW in Wᵢ}. The function linearize (wall polygon) may return the line that is parallel to the wall polygon's longest edge, and may be the longest line possible of that rotation such that the line is entirely inside the polygon. H may represent walls in linear format rather than polygon format.

Certain example embodiments may measure the repetitiveness and alignment of the rooms within the layout. The repetitiveness may be calculated as the quantity of the elements ((A1, A2), (B1, B2))∈H×H where f(A1, A2, B1, B2)==True. f(A1, A2, B1, B2) may be calculated as ((A1, A2)∥(p1, p2))∧((A1, p1)∥(A2, p2))∧((A1, A2)⊥(A1, p1))∧((A1, A2)⊥(A2, p2)), where p1 may be whichever of B1 and B2 is closer to A1; p2 may be whichever of B1 and B2 is not p1; A1, B1, A2, B2 may be points; and (x,y) may be a line between points x and y. This may calculate how many rooms are aligned in a repetitive manner. For example, this count may be divided by |H|² to normalize between 0 and 1. In certain example embodiments, a preference may be set by in the software or by a user for a lower count or higher count. Furthermore, 1−f(x) may be applied to the output value to prioritize floorplans that are less repetitive rather than more repetitive. For example, simple offices may be desired to be more repetitive, while in contrast, highly artistic buildings may be desired to be less repetitive. In some example embodiments, the output may be multiplied by a number (e.g., 10), and the result may be capped at 1. Furthermore, in some embodiments, a wall may only be matched with one other wall before it is removed from the set; this causes n matching lines to score O(N) rather than O(N²).

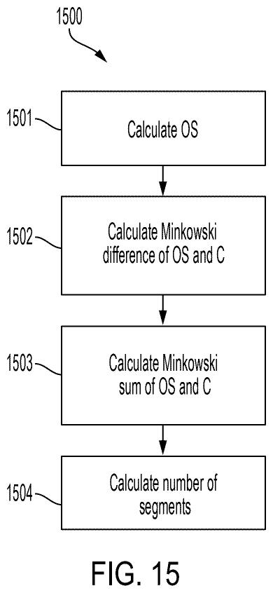

Some example embodiments may measure the simplicity of shape of open areas. For example, as shown in FIG. 15, the simplicity of shape of open areas may be calculated by, as shown at step 1501, OS=T\∪_{R}_{ᵢ}_{∈R} Rᵢ. At step 1502, the method may include calculating the Minkowski difference of OS and C, where C is a circle of width d centered at the origin. At step 1503, the method may include calculating the Minkowski sum of the polygon calculated in step 1502 above and C, where C is a circle of width d centered at the origin. At step 1504, the method may further include calculating the number of segments from the result of step 1503. As an example, ‘d’ may be 3 times the minimum width of a hallway required in building code. In other examples, ‘d’ may be a constant from 0 to the diagonal length of the floorplan. ‘d’ may also be determined as a function of the floorplan's elements or size, such as a function of the floorplan's diagonal length. An ideal open area shape may include a rectangle and/or L-shaped hexagon; shapes with additional complexity may have undesirable open area space. The count may be mapped to between 0 to 1 by passing the value into a linear function that goes through (4, 1) and (14,0), then trimming this result to between 0 and 1. For example, this mapping function may include any of the other mapping functions discussed herein. In some embodiments, the count may be first divided by the number of distinct polygons produced after taking the Minkowski sum.

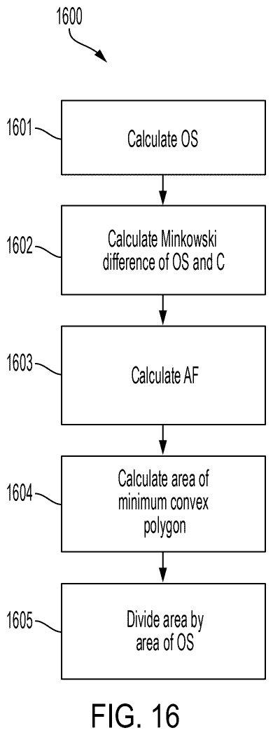

Various example embodiments may include measuring the openness of an open space. For example, as shown in FIG. 16, the method may include, at step 1601, calculating OS=T\∪_{R}_{ᵢ}_{∈R} Rᵢ. At step 1602, the method may further include calculating the Minkowski difference of OS and C, where C is a circle of width d centered at the origin. At step 1603, the method may further include calculating AF=Minkowski sum of the result of step 1602 and C, where C is a circle of width d centered at the origin. At step 1604, the method may further include calculating the area of the minimum convex polygon that fits inside AF and that only has corner points from the set of AF's corner points. At step 1605, the method may further include dividing the value from step 1604 by the area of OS. This method may prioritize having an open area that is a large convex polygon. A minimum convex polygon within another polygon may be calculated by triangulating the starting polygon, then determining which combination of triangles forms the largest polygon. As an example, ‘d’ may be 2 times the minimum width of a hallway required in building code. As another example, ‘d’ may be a constant from 0 to the diagonal length of the floorplan. ‘d’ can also be determined as a function of the floorplan's elements or size, such as a function of the floorplan's diagonal length.

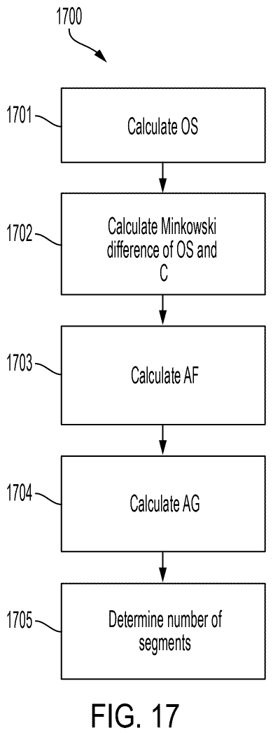

Certain example embodiments may measure the simplicity of the hallway path. For example, as shown in FIG. 17, the method may include, at step 1701, calculating OS=T \ ∪_{R}_{ᵢ}_{∈R} Rᵢ. At step 1702, the method may further include calculating the Minkowski difference of OS and C, where C is a circle of width d centered at the origin. At step 1703, the method may further include calculating AF=Minkowski sum of the result of step 1702 and C, where C is a circle of width d centered at the origin. At step 1704, the method may further include calculating AG=T\AF. AG may represent the polygon (or multi-polygon) of hallways for the floorplate. At step 1705, the method may further include determining the number of segments in AG's edges. The effect of this technique may be to deprioritize both jagged hallway lines and complex hallways. In various example embodiments, ‘d’ may be 2 times the minimum width of a hallway required by building code. In other example embodiments, ‘d’ may be a constant from 0 to the diagonal length of the floorplan. ‘d’ may also be determined as a function of the floorplan's elements or size, such as a function of the floorplan's diagonal length. In various example embodiments, the count may be mapped to between 0 to 1 by applying a linear function that goes through (6, 1) and (24,0), then trimming this result to between 0 and 1. In some example embodiments, a different mapping function may be any of the other mapping functions discussed herein. In some embodiments, the count may first be divided by the number of distinct polygons in AG before applying a mapping function. Taking the Minkowski difference of polygon1 and polygon2, and then taking the Minkowski sum of that result and polygon2, may yield a polygon similar to polygon1 but with any small extended areas removed.

Some example embodiments may minimize hallway area by calculating the area of AG; this value may be divided by the area of T then mapped by f(x)=1−x. In certain example embodiments, other mapping techniques described herein may be used.

Various example embodiments minimize hallway length by calculating the longest flood-fill distance in AG from any point in AG to any other point in AG. This value may be divided by the diagonal length in F, trimmed to be within 0 to 1, then mapped by f(x)=1−x. In some example embodiments, other mapping techniques described herein may be used.

In certain example embodiments, hallway loops (e.g., continuous non-overlapping paths through hallways that start and end at the same position) may be minimized by splitting AG into distinct polygons. For each polygon, a random edge may be selected, and the edges traversed (while marking each) until the initial edge is reached again. If all edges have not been marked in the traversal, it may be determined that a loop exists in the polygon. A first value (e.g., 1) may denote no loops in any polygon, and a second value (e.g., 0) may denote loops in the polygon.

Some example embodiments may determine whether HVAC vents are optimally laid out for the floorplan by calculating how much heat could escape. The minimum and maximum temperatures that the building is designed for may be set by the user, or have predefined defaults (e.g., 23° C.≤x≤26° C.). In some example embodiments, multiple zones in the floorplan may have different desired temperature ranges. The insulation of the external walls and windows may be determined for an existing shell; otherwise, an R value (e.g., 4) per inch of external wall depth may be used. For internal walls, an insulation value (e.g., 4) per inch of internal wall depth may be used. The temperatures that are beyond the third standard deviation (in the low and high directions) based on local historical temperatures for the location may be determined. The function may be calculated by first summing the British thermal units (BTU) heat lost per hour in the coldest design case plus the amount of BTU cooling lost per hour in the hottest design case. This quantity may then be divided by the square foot area of the floorplate. The previous value may be divided by 60*2, capped to a maximum of 1, then subtracted from 1.

Various example embodiments may prioritize layouts that have the posts and/or structural supports contained within internal walls by calculating the number of posts and/or structural supports within internal walls, then dividing this number by the total number of posts and/or structural supports in the floorplate.

In certain example embodiments, a probability density function may be embedded in two primary ways. A dense embedding may be stored as an array of values across a grid, while a sparse embedding may be stored as a list of values at specific positions.

For example, one method for embedding a probability density function may include explicitly calculating a value of the probability density function at a set of points. Another example may include embedding a probability density function by first sampling a room element, and then sampling a position by a function dependent on that room element's position, even if the convoluted probability density function is not explicitly stored in computer memory.

A Dirac delta function (e.g., δ distribution, wherein the unit impulse may be a generalized function on the real numbers, whose value is zero everywhere except at a value, and its integral over the entire real line is equal to one), a convolution of Dirac delta functions, and a uniform distribution are all examples of probability density functions.

As used throughout this disclosure, the term “floorplan” may refer to any set of rooms which includes one or more rooms. A floorplan can be represented in a computer without being drawn, and may be a set of rooms that fills a portion or all of a polygon or shape. A floorplan may be a space that is not bounded by exterior walls. A floorplan may be a space with an outer bound fully or partially specified by the user.

The “width” of a “path” may be a variety of measurements, such as a measure of the widest object that can fit through the path's shape; a straight line drawn between two points on a shape's edges; or a calculation that correlates with a width measure of a shape.

The phrase “determine a corner offset” may refer to determining sufficient information such that the relative position of one corner point from another corner point could be determined. In one example, the center point of a square room may be determined then the width of the room is determined; the corner offset between the upper two corners may have been set because there is sufficient information to determine the relative position of the top left corner from the top right corner.

Determining a position of a room may refer to determining the position of at least one point in a room (e.g., the room's center, the room's top left corner). A room's position may be determined by defining it relative to another point/origin, which may later have its position determined.

A floorplan scoring function may be any function that calculates a sortable or filterable metric from a floorplan.

A building with multiple segments and/or floors may be split into multiple floorplates and parts of certain embodiments may be run on one or more of the floorplates.

Some example embodiments may prioritize layouts that have walls that terminate inline with the mullions of external curtain walls, rather than walls that align with the center of windows in the curtain wall. This may be calculated as the number of walls that terminate inline with a mullion, divided by the total number of walls that terminate into curtain walls (e.g., either a mullion or center of a window).

Certain example embodiments may determine whether a floorplan conforms to building code requirements (e.g., the presence of dead ends, the maximum distance to exits, and/or the minimum hallway width for a given flow of people through a path). If the floorplan conforms to building code, then a value of 1 may be returned by this function. Otherwise, a value of 0 may be returned.

Various example embodiments may calculate the average amount of natural lighting that reaches spaces by using ray tracing to determine the light that reaches each square foot of the space for each of a set of (e.g., 100) sun positions randomly sampled from the yearly day-time sun positions for the building. The daylight factor may be calculated for each position. For example, a daylight factor of at least 2% may be satisfactory. The score may be the percentage of the space that has a daylight factor of at least 2% across all 100 tested sun positions. As another example, a different daylight factor threshold may be used. In some example embodiments, a different daylight factor threshold may be used for each different room type. In some example embodiments, the ray tracing may include the light that enters via both windows and skylights.

Throughout this disclosure, many operations are performed on 2D rooms, walls, and various other elements. These various elements may represent 3D spaces, which may have constant or complex varied heights.

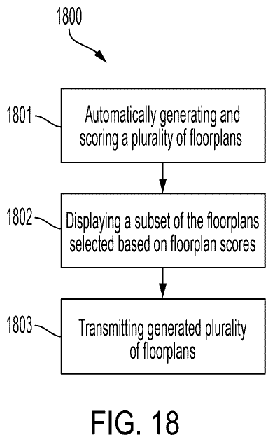

As shown in FIG. 18, the method may include, at step 1801, automatically generating and scoring a plurality of floorplans.

At step 1802, the method may further include displaying, in an interactive computerized user interface, a subset of the generated plurality of floorplans that has been selected based on the scores of the floorplans.

At step 1803, the method may further include, based upon input from the interactive computerized user interface, transmitting at least one of the generated plurality of floorplans.

FIG. 19 illustrates an example of a system according to certain example embodiments. In one example embodiment, a system may include multiple devices, such as, for example, computing device 1910.

Computing device 1910 may include one or more of a mobile device, such as a mobile phone, smart phone, personal digital assistant (PDA), tablet, or portable media player, digital camera, pocket video camera, video game console, navigation unit, such as a global positioning system (GPS) device, desktop or laptop computer, single-location device, such as a sensor or smart meter, or any combination thereof.

Computing device 1910 may include at least one processor, respectively indicated as 1911. Processor 1911 may be embodied by any computational or data processing device, such as a central processing unit (CPU), application specific integrated circuit (ASIC), or comparable device. The processors may be implemented as a single controller, or a plurality of controllers or processors.

At least one memory may be provided in one or more of the devices, as indicated at 1912. The memory may be fixed or removable. The memory may include computer program instructions or computer code contained therein. Memory 1912 may independently be any suitable storage device, such as a non-transitory computer-readable medium. The term “non-transitory,” as used herein, may correspond to a limitation of the medium itself (i.e., tangible, not a signal) as opposed to a limitation on data storage persistency (e.g., random access memory (RAM) vs. read-only memory (ROM)). A hard disk drive (HDD), random access memory (RAM), flash memory, or other suitable memory may be used. The memories may be combined on a single integrated circuit as the processor, or may be separate from the one or more processors. Furthermore, the computer program instructions stored in the memory, and which may be processed by the processors, may be any suitable form of computer program code, for example, a compiled or interpreted computer program written in any suitable programming language.

Processor 1911, memory 1912, and any subset thereof, may be configured to provide means corresponding to the various blocks of FIGS. 4-17. Although not shown, the devices may also include positioning hardware, such as GPS or micro electrical mechanical system (MEMS) hardware, which may be used to determine a location of the device. Other sensors are also permitted, and may be configured to determine location, elevation, velocity, orientation, and so forth, such as barometers, compasses, and the like.

As shown in FIG. 19, transceiver 1913 may be provided, and one or more devices may also include at least one antenna, illustrated as 1914. The device may have many antennas, such as an array of antennas configured for multiple input multiple output (MIMO) communications, or multiple antennas for multiple RATs. Other configurations of these devices, for example, may be provided. Transceiver 1913 may be a transmitter, a receiver, both a transmitter and a receiver, or a unit or device that may be configured both for transmission and reception.

The memory and the computer program instructions may be configured, with the processor for the particular device, to cause a hardware apparatus, such as UE, to perform any of the processes described above (i.e., FIGS. 4-17). Therefore, in certain example embodiments, a non-transitory computer-readable medium may be encoded with computer instructions that, when executed in hardware, perform a process such as one of the processes described herein. Alternatively, certain example embodiments may be performed entirely in hardware.

In certain example embodiments, an apparatus may include circuitry configured to perform any of the processes or functions illustrated in FIGS. 4-17. As used in this application, the term “circuitry” may refer to one or more or all of the following: (a) hardware-only circuit implementations (such as implementations in only analog and/or digital circuitry), (b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions), and (c) hardware circuit(s) and or processor(s), such as a microprocessor(s) or a portion of a microprocessor(s), that requires software (e.g., firmware) for operation, but the software may not be present when it is not needed for operation. This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

According to certain example embodiments, processor 1911 and memory 1912, may be included in or may form a part of processing circuitry or control circuitry. In addition, in some example embodiments, transceiver 1913 may be included in or may form a part of transceiving circuitry.

In some example embodiments, an apparatus (e.g., computing device 1910) may include means for performing a method, a process, or any of the variants discussed herein. Examples of the means may include one or more processors, memory, controllers, transmitters, receivers, and/or computer program code for causing the performance of the operations.

The features, structures, or characteristics of example embodiments described throughout this specification may be combined in any suitable manner in one or more example embodiments. For example, the usage of the phrases “various embodiments,” “certain embodiments,” “some embodiments,” or other similar language throughout this specification refers to the fact that a particular feature, structure, or characteristic described in connection with an example embodiment may be included in at least one example embodiment. Thus, appearances of the phrases “in various embodiments,” “in certain embodiments,” “in some embodiments,” or other similar language throughout this specification does not necessarily all refer to the same group of example embodiments, and the described features, structures, or characteristics may be combined in any suitable manner in one or more example embodiments.

As used herein, “at least one of the following: <a list of two or more elements>” and “at least one of <a list of two or more elements>” and similar wording, where the list of two or more elements are joined by “and” or “or,” mean at least any one of the elements, or at least any two or more of the elements, or at least all the elements.

Additionally, if desired, the different functions or procedures discussed above may be performed in a different order and/or concurrently with each other. Furthermore, if desired, one or more of the described functions or procedures may be optional or may be combined. As such, the description above should be considered as illustrative of the principles and teachings of certain example embodiments, and not in limitation thereof.

One having ordinary skill in the art will readily understand that the example embodiments discussed above may be practiced with procedures in a different order, and/or with hardware elements in configurations which are different than those which are disclosed. Therefore, although some embodiments have been described based upon these example embodiments, it would be apparent to those of skill in the art that certain modifications, variations, and alternative constructions would be apparent, while remaining within the spirit and scope of the example embodiments.

CLAUSE 1: A computerized method, comprising automatically generating a plurality of floorplans, wherein for each floorplan of a plurality of floorplans: determining a position to place a room within a respective floorplan based upon a position of a structural support; and creating a room within the respective floorplan, wherein at least one of the room's corner offsets is determined after at least one other room's position has been determined, scoring a plurality of generated floorplans according to a scoring function, calculating, for at least one generated floorplan, whether it has a path with width at least as large as a number from a door of the respective generated floorplan to an exit, displaying, in an interactive computerized user interface, a subset of the generated plurality of floorplans that has been selected based on the scores of the floorplans, and based upon input from the interactive computerized user interface, transmitting at least one of the generated plurality of floorplans.

CLAUSE 2: The method of clause 1, wherein the number for the path width is the width defined by the applicable building code.

CLAUSE 3: The method of clause 1 or 2, further comprising determining a polygon that shares an edge with each of a subset of doors from a floorplan.

CLAUSE 4: The method of any of clauses 1-3, further comprising calculating the number of line segments in at least one polygon.

CLAUSE 5: The method of any of clauses 1-4, further comprising calculating the dead space in each of a plurality of floorplans.

CLAUSE 6: A system, comprising: at least one processor; and at least one memory storing instructions, wherein the instructions, when executed by the at least one processor, cause the apparatus at least to: automatically generate a plurality of floorplans, wherein for each floorplan of a plurality of floorplans: determine a position to place a room within a respective floorplan based upon a position of a structural support; and create a room within the respective floorplan, wherein at least one of the room's corner offsets is determined after at least one other room's position has been determined, score a plurality of generated floorplans according to a scoring function, calculate, for at least one generated floorplan, whether it has a path with width at least as large as a number from a door of the respective generated floorplan to an exit, display, in an interactive computerized user interface, a subset of the generated plurality of floorplans that has been selected based on the scores of the floorplans, and based upon input from the interactive computerized user interface, transmit at least one of the generated plurality of floorplans.

CLAUSE 7: The system according to clause 6, wherein the number for the path width is the width defined by the applicable building code.

CLAUSE 8: The system of clause 6 or 7, wherein the at least one memory stores instructions that when executed by the at least one processor, further cause the apparatus at least to: determine a polygon that shares an edge with each of a subset of doors from a floorplan.

CLAUSE 9: The system of any of clauses 6-8, wherein the at least one memory stores instructions that when executed by the at least one processor, further cause the apparatus at least to: calculate the number of line segments in at least one polygon.

CLAUSE 10: The system of any of clauses 6-9, wherein the at least one memory stores instructions that when executed by the at least one processor, further cause the apparatus at least to: calculate the number of line segments in at least one polygon.

CLAUSE 11: The system of any of clauses 6-10, wherein the at least one memory stores instructions that when executed by the at least one processor, further cause the apparatus at least to: calculate the dead space in each of a plurality of floorplans.

CLAUSE 12: At least one processor, comprising: processing circuitry to automatically generate a plurality of floorplans, wherein for each floorplan of a plurality of floorplans: determine a position to place a room within a respective floorplan based upon a position of a structural support; and create a room within the respective floorplan, wherein at least one of the room's corner offsets is determined after at least one other room's position has been determined, score a plurality of generated floorplans according to a scoring function, calculate, for at least one generated floorplan, whether it has a path with width at least as large as a number from a door of the respective generated floorplan to an exit, display, in an interactive computerized user interface, a subset of the generated plurality of floorplans that has been selected based on the scores of the floorplans, and based upon input from the interactive computerized user interface, transmit at least one of the generated plurality of floorplans.

Any and all combinations of any of the claim elements recited in any of the claims and/or any elements or clauses described in this application, in any fashion, fall within the contemplated scope of the present disclosure and protection.

### Partial Glossary

2D Two-Dimensional
3D Three-Dimensional
Btu British Thermal Units
CAD Computer-Aided Design
CPU Central Processing Unit
CSV Comma-Separated Value
CU Centralized Unit
GPS Global Positioning System
HDD Hard Disk Drive
HVAC Heating, Ventilation, and Air Conditioning
IoT Internet of Things
MEMS Micro Electrical Mechanical System
MIMO Multiple Input Multiple Output
mMTC Massive Machine Type Communication
PDA Personal Digital Assistance
RAM Random Access Memory
RF Radio Frequency
ROM Read-Only Memory
ST Standard Deviation
UI User Interface
WLAN Wireless Local Area Network

We claim:

1. A computerized method for automatically generating an optimized floorplan comprising:
automatically generating a plurality of floorplans, wherein for each floorplan of a plurality of floorplans:
determining a position to place a room within a respective floorplan based upon a position of a structural support; and
creating a room within the respective floorplan, wherein at least one of the room's corner offsets is determined after at least one other room's position has been determined;
scoring a plurality of generated floorplans according to a scoring function;
calculating, for at least one generated floorplan, whether it has a path with width at least as large as a number from a door of the respective generated floorplan to an exit;
displaying, in an interactive computerized user interface, a subset of the generated plurality of floorplans that has been selected based on the scores of the floorplans; and
based upon input from the interactive computerized user interface, transmitting at least one of the generated plurality of floorplans.

2. The computerized method of claim 1, wherein the number for the path width is the width defined by the applicable building code.

3. The computerized method of claim 1, further comprising:
determining a polygon that shares an edge with each of a subset of doors from a floorplan.

4. The method of claim 1, further comprising:
calculating the number of line segments in at least one polygon.

5. The method of claim 1, further comprising:
calculating the dead space in each of a plurality of floorplans.

6. A non-transitory computer readable medium comprising program instructions that, when executed by an apparatus, cause the apparatus to perform a computerized method for automatically generating an optimized floorplan comprising:
automatically generating a plurality of floorplans, wherein for each floorplan of a plurality of floorplans:
determining a position to place a room within a respective floorplan based upon a position of a structural support; and
creating a room within the respective floorplan, wherein at least one of the room's corner offsets is determined after at least one other room's position has been determined;
scoring a plurality of generated floorplans according to a scoring function;
calculating, for at least one generated floorplan, whether it has a path with width at least as large as a number from a door of the respective generated floorplan to an exit;
displaying, in an interactive computerized user interface, a subset of the generated plurality of floorplans that has been selected based on the scores of the floorplans; and
based upon input from the interactive computerized user interface, transmitting at least one of the generated plurality of floorplans.

7. The non-transitory computer readable medium of claim 6, wherein the number for the path width is the width defined by the applicable building code.

8. The non-transitory computer readable medium of claim 6, further comprising:
determining a polygon that shares an edge with each of a subset of doors from a floorplan.

9. The non-transitory computer readable medium of claim 6, further comprising:
calculating the number of line segments in at least one polygon.

10. The non-transitory computer readable medium of claim 6, further comprising:
calculating the dead space in each of a plurality of floorplans.

11. An apparatus comprising:
at least one processor; and
at least one memory storing instructions that, when executed by the at least one processor, cause the apparatus at least to:
automatically generate a plurality of floorplans, wherein for each floorplan of a plurality of floorplans:
determine a position to place a room within a respective floorplan based upon a position of a structural support; and
create a room within the respective floorplan, wherein at least one of the room's corner offsets is determined after at least one other room's position has been determined;
score a plurality of generated floorplans according to a scoring function;
calculate, for at least one generated floorplan, whether it has a path with width at least as large as a number from a door of the respective generated floorplan to an exit;
display, in an interactive computerized user interface, a subset of the generated plurality of floorplans that has been selected based on the scores of the floorplans; and
based upon input from the interactive computerized user interface, transmit at least one of the generated plurality of floorplans.

12. The apparatus of claim 11, wherein the number for the path width is the width defined by the applicable building code.

13. The apparatus of claim 11, wherein the at least one memory and the instructions, when executed by the at least one processor, further cause the apparatus at least to:
determine a polygon that shares an edge with each of a subset of doors from a floorplan.

14. The apparatus of claim 11, wherein the at least one memory and the instructions, when executed by the at least one processor, further cause the apparatus at least to:
calculate the number of line segments in at least one polygon.

15. The apparatus of claim 11, wherein the at least one memory and the instructions, when executed by the at least one processor, further cause the apparatus at least to:
calculate the dead space in each of a plurality of floorplans.
